(19) United States
(12) Patent Application Publication
(10) Pub. No.: US 2002/0070457 A1
(43) Pub. Date: Jun. 13, 2002

(54) Metal contact structure in semiconductor device and method for forming the same

(75) Inventors: Ho-Won Sun, Kyungki-do (KR); Kang-Yoon Lee, Kyungki-do (KR); Jeong-Seok Kim, Kyungki-do (KR); Dong-Won Shin, Kyungki-do (KR); Tai-Heui Cho, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/010,604

(22) Filed: Nov. 8, 2001

(30) Foreign Application Priority Data
Dec. 9, 2000 (KR) 00-74916

(51) Int. Cl. H01L 21/4763; H01L 23/52; H01L 29/40

(52) U.S. Cl. 257/774; 438/637; 438/640; 438/628; 257/751

(57) ABSTRACT

A metal contact structure of a semiconductor device and a method for forming the same are provided. The diameter of the upper portion of a contact hole that exposes a region of a lower conductive layer is formed to be larger than the diameter of the lower portion of the contact hole. The metal contact structure is formed without a void or a key hole. This is accomplished by forming at least two metal layers to fill the contact hole by performing a first deposition, an etch back, and a second deposition. The metal layer which fills the contact hole is etched back using a barrier metal layer formed on the entire surface of the contact hole as an etching stop layer. Thus, a void or key hole is not generated by making the upper portion of the contact hole to be wider than the lower portion of the contact hole and by depositing the metal which fills the contact hole through the processes of firstly depositing the metal, etching back the metal, and secondly depositing the metal.

### BACKGROUND OF THE INVENTION

1. Field of the Invention

The present invention relates to a semiconductor device, and more particularly, to a metal contact structure in a semiconductor device and a method forming the same.

2. Description of the Related Art

In general, a semiconductor device is formed by stacking a predetermined conductive layer and an interlayer dielectric film on a semiconductor substrate. The conductive layer includes a wiring through which an electrical signal is transmitted. Polycrystalline silicon doped with impurities is mainly used as a material for the wiring.

Recently, attention has been devoted to a method of using a metal such as tungsten, aluminum, copper, or metal silicide, which has an excellent conductive characteristic, as the wiring material instead of polycrystalline silicon doped with impurities.

In general, a metal wiring structure includes a wiring longitudinally extended in a horizontal direction parallel to the surface of a substrate and a contact structure that is electrically connected to an active region of a substrate, that is, a final destination of an electrical signal, or for connecting a lower conductive layer to the wiring in a vertical direction. The contact structure is formed in an upper conductive layer (an upper wiring) and a lower conductive layer (a lower wiring), between which an interlayer dielectric film is interposed, and includes a contact plug for connecting the upper and lower conductive layers to each other. A contact hole is formed in the interlayer dielectric film. The contact hole is filled with a contact plug. The upper conductive layer can operate as a contact plug while filling the contact hole without the contact plug. When the upper conductive layer formed of a metal operates as the contact plug without an additional contact plug or when an additional contact plug formed of a metal exists, such a contact structure is referred to as the metal contact structure.

As the integration density of a semiconductor device increases and thus, the width of the conductive layer (the wiring) is reduced and the aspect ratio of the contact hole increases, many problems occur in forming the metal contact structure. For example, contact resistance increases due to the reduction of a contact area. Also, contact resistance increases and contact reliability deteriorates due to a void or a key hole generated when a metal is deposited in a high aspect ratio contact hole.

FIG. 1 is a sectional view showing a conventional metal contact structure. The metal contact structure shown in FIG. 1 includes a lower conductive layer 20 formed on a substrate 10, an interlayer dielectric film 30, in which a contact hole that exposes the lower conductive layer 20 is formed, a metal contact plug 60 that fills the contact hole and connects the lower conductive layer 20 and an upper conductive layer 70, and the upper conductive layer 70. As the aspect ratio of the contact hole increases, namely, as the contact hole becomes deeper and narrower, it is difficult to completely fill the contact hole with a metal, such as tungsten, because, as shown in FIG. 1, a void 65 or a key hole is generated in the contact plug 60. The void 65 or the key hole increases the contact resistance and deteriorates the reliability of the contact.

In order to prevent the void or the key hole, as stated in Korean Patent Publication No. 1998-55920, after firstly depositing tungsten in order to form a contact plug and entirely etching back the deposited W about 20%, tungsten is secondly deposited. However, in such a method, problems may occur since tungsten is unevenly removed when the etching uniformity of the entire wafer during the etch back of tungsten is considered. In Korean Patent Publication No. 1998-55921, a mask is formed on the contact plug and ions are implanted before entirely etching back tungsten to form a contact plug. Accordingly, a method of preventing the generation of the key hole by different etching rates according to whether ions are implanted is provided. However, the method is susceptible to the generation of a void and is not productive since a photolithography process and an ion implantation process must be performed.

### SUMMARY OF THE INVENTION

To solve the above problems, it is an object of the present invention to provide a metal contact structure of a semiconductor device in which a void or a key hole is not generated.

It is another object of the present invention to provide a method for forming a metal contact structure of a semiconductor device without a void.

Accordingly, to achieve the first object, a metal contact structure of a semiconductor device includes a lower conductive layer, an interlayer dielectric film with a contact hole formed in the interdielectric film and exposing the lower conductive layer wherein the diameter of the upper portion of the contact hole is larger than the diameter of the lower portion of the contact hole, and an upper wiring composing at least two metal layers including a lower metal layer on the lower conductive layer filling some of the contact hole and formed of a metal and an upper metal layer filling the remaining portion of the contact hole and formed of a metal on the lower metal layer.

The upper wiring can operate as a wiring, while filling the contact hole by the upper and lower metal layer without an additional contact plug, and can be formed of a contact plug that is formed of the upper and lower metal layer and fills the contact hole and an upper conductive layer formed on the contact plug to have a predetermined pattern.

To achieve the second object, according to a method of the present invention, a metal contact structure is formed without a void or a key hole by forming a contact hole that exposes a lower conductive layer so that the diameter of the upper portion of the contact hole is larger than the diameter of the lower portion of the contact hole and creating at least two metal layers that fill the contact hole by performing first deposition, etch back, and second deposition. Namely, for forming the metal contact structure according to the present invention, the contact hole, which exposes the lower conductive layer, has an upper portion diameter larger than a lower portion diameter by forming an interlayer dielectric film on a substrate, on which the lower conductive layer is formed, and etching the interlayer dielectric film. After forming a barrier metal layer on the surface of the interlayer dielectric film including surfaces inside the contact hole, a conductive metal is deposited on the surface of the barrier metal layer so that the contact hole is not completely filled. The surface of the deposited metal is etched back with the barrier metal layer used as an etching stop layer so that some metal is left inside the contact hole while substantially all of the metal outside the contact hole is removed. The metal is deposited again on the surface of the etched-back resulting sturcutre.

According to a first embodiment, the interlayer dielectric film is formed by sequentially depositing at least two different layers having different etching rates with respect to a predetermined etchant. As for the contact hole, the contact hole having the above-mentioned shape is formed by dry or wet etching the interlayer dielectric film using an etchant that etches an upper interlayer dielectric film more than a lower interlayer dielectric film.

According to a second embodiment, after forming an etching mask that defines the contact hole on the interlayer dielectric film and isotropically etching the interlayer dielectric film using the etching mask, the contact hole having the above-mentioned shape is formed by anisotropically etching the interlayer dielectric film using the etching mask.

It is possible to directly form an upper wiring by patterning the secondly deposited metal layer. Also, it is possible to form an independent upper conductive layer for the wiring using the secondly deposited metal layer as the contact plug.

When the aspect ratio of the contact hole is high, the contact hole can be filled without a void or key hole by repeatedly performing the steps of etching back the deposited metal using the barrier metal layer as the etching stop layer and depositing the metal again, after the deposition of the upper metal layer.

### BRIEF DESCRIPTION OF THE DRAWING(S)

The above objects and advantages of the present invention will become more apparent by describing in detail a preferred embodiment thereof with reference to the attached drawings in which:

FIG. 1 is a sectional view showing a conventional metal contact structure;

FIGS. 2A and 2B are sectional views showing a metal contact structure according to a first embodiment of the present invention;

FIGS. 3A and 3B are sectional views showing a metal contact structure according to a second embodiment of the present invention;

FIGS. 4A through 4C are sectional views showing the processes of forming a metal contact structure according to the first embodiment of the present invention; and

FIG. 5 is a sectional view showing a process of forming a metal contact structure according to the second embodiment of the present invention.

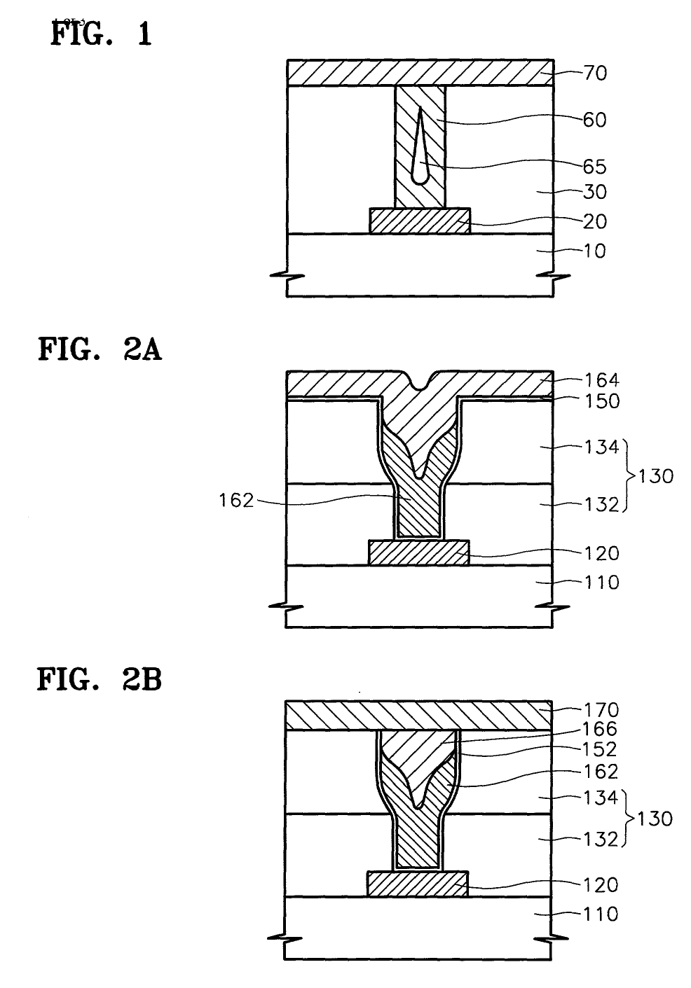

### DESCRIPTION OF THE PREFERRED EMBODIMENT(S)

The present invention now will be described more fully with reference to the accompanying drawings, in which preferred embodiments of the invention are shown. In the drawings, the thickness of layers and regions are exaggerated for clarity. It will also be understood that when a layer is referred to as being □on□ another layer or substrate, it can be directly on the other layer or substrate, or intervening layers may also be present. The same reference numerals in different drawings represent the same element.

FIGS. 2A and 2B are sectional views showing a metal contact structure according to a first embodiment of the present invention.

Referring to FIG. 2A, a predetermined lower conductive layer 120 is formed on a substrate 110. An interlayer dielectric film 130 overlies the substrate 110 including the lower conductive layer 120. A contact hole that exposes a region of the lower conductive layer 120 is formed in the interlayer dielectric film 130. An upper wiring comprises lower and upper metals layers 162 and 164 that fill the contact hole is formed. Reference numeral 150 denotes a barrier metal layer for preventing the metal that forms the upper wiring from being diffused to the lower conductive layer 120 and through the interlayer dielectric film 130. The barrier metal layer 150 is commonly formed by stacking a Ti film and a TiN film. However, the barrier metal layer 150 can be formed of other metal films such as a Ta film, a TaN film or a metal nitride film.

The lower conductive layer 120 may be a gate electrode, a bit line contact pad, a lower wiring of multiple metal wiring formed in the upper layer of an element (in this case, the substrate 110 becomes an interlayer dielectric film on which other elements are formed), or a source/drain region formed in the substrate 110. The lower conductive layer 120 may be formed of a conductive material such as polycrystalline silicon, metal silicide, aluminum, or copper.

The interlayer dielectric film 130 is, in general, formed of a silicon-oxide-film family. In particular, the interlayer dielectric film of the first embodiment consists of two layers 132 and 134 formed of different materials having different etch rates with respect to a predetermined etchant. To be specific, a lower interlayer dielectric film 132 is formed of plasma enhanced tetraethylorthosilicate (PE-TEOS) or phosphorous silicate glass (PSG) and an upper interlayer dielectric film 134 is formed of spin-on glass (SOG) of undoped silicate glass (USG). When the upper and lower interlayer dielectric films 134 and 132 are formed of the above materials, it is possible to obtain a contact hole with the upper portion having a larger diameter than the lower portion since the etching ratio of the upper interlayer dielectric film 134 is greater than the etching ratio of the lower interlayer dielectric film 132 with respect to an etchant including an HF solution. The interlayer dielectric film 130 consists of two layers 132 and 134 in the drawings, but may consist of more than two layers with an etching ratio that increases toward upper layers.

The lower metal layer 162 of the upper wiring fills the low portion of the contact hole and is connected to the lower conductive layer 120 with the barrier metal layer 150 interposed therebetween. The upper metal layer 164 fills the rest of the contact hole. Namely, the upper wiring of the metal contact structure can operate as a contact plug without an additional contact plug. However, the lower metal layer 162 may be referred to as the contact plug and the upper metal layer 164 may be referred to as the upper wiring.

Though mentioned later, the upper wiring of the first embodiment can achieve an excellent profile that does not include a void or a key hole by firstly depositing a metal on the entire surface of the interlayer dielectric film 130 including the contact hole, in which the barrier metal layer 150 is formed, forming the lower metal layer 162 by etching back the firstly deposited metal using the barrier metal layer 150 as an etching stop layer, and forming the upper metal layer 164 by secondly depositing a metal on the lower metal layer 162. The upper and lower metal layers 164 and 162 can be formed of a metal such as W or Al and can be formed of the same material or different materials. In particular, when the aspect ratio of the contact hole is large, the upper wiring may be two layers of metal 162 and 164 as illustrated in the drawings. However, the upper wiring may consist of more than two layers.

FIG. 2B is a modification of the first embodiment in which an independent contact plug exists. Namely, a contact plug formed of the lower metal layer 162 and the planarized upper metal layer 166 is formed by planarizing the upper metal layer 164 of FIG. 2A by a chemical mechanical polishing (CMP) or etch back process, thus removing it from the upper portion of the interlayer dielectric film 130. An upper conductive layer 170, which is used for wiring, is formed on the contact plug. Here, the planarized upper metal layer 166 and the lower metal layer 164 may be formed of W. The upper conductive layer 170 may be formed of Al. Though not shown, the upper conductive layer 170 may be formed after the barrier metal layer 150 is formed by stacking a Ti film and a TiN film on the planarized upper metal layer 166 and the upper interlayer dielectric film 134 that have been planarized by the CMP or etch back. Since the other elements are the same as shown in the metal contact structure of FIG. 2A, a detailed description thereof will be omitted.

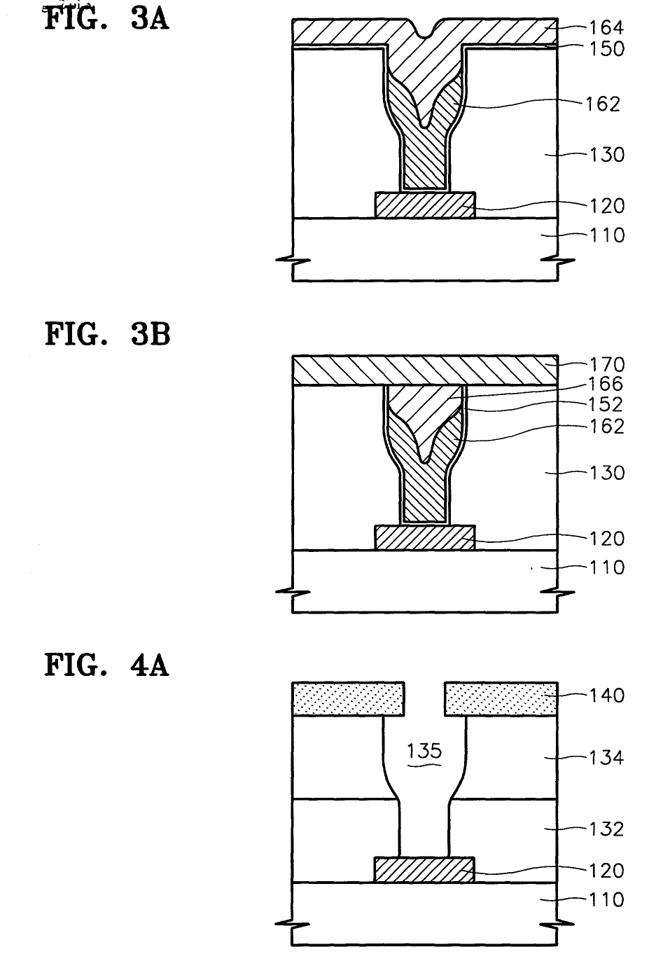

FIGS. 3A and 3B are sectional views showing a metal contact structure according to second embodiment of the present invention. The metal contact structure of the second embodiment is the same as the metal contact structure of the first embodiment except that the interlayer dielectric film 130 is formed of a single layer. In the first embodiment, the interlayer dielectric film 130 consists of two different layers 132 and 134 having different etch rates in order to obtain the contact hole unique to the present invention. However, it is not necessary that the interlayer dielectric film 130 includes two different layers if it is possible to obtain the same contact hole with an interlayer dielectric film 130 consisting of one film. A method of obtaining the contact hole with the upper portion wider than the lower portion, according to the second embodiment, will be described later.

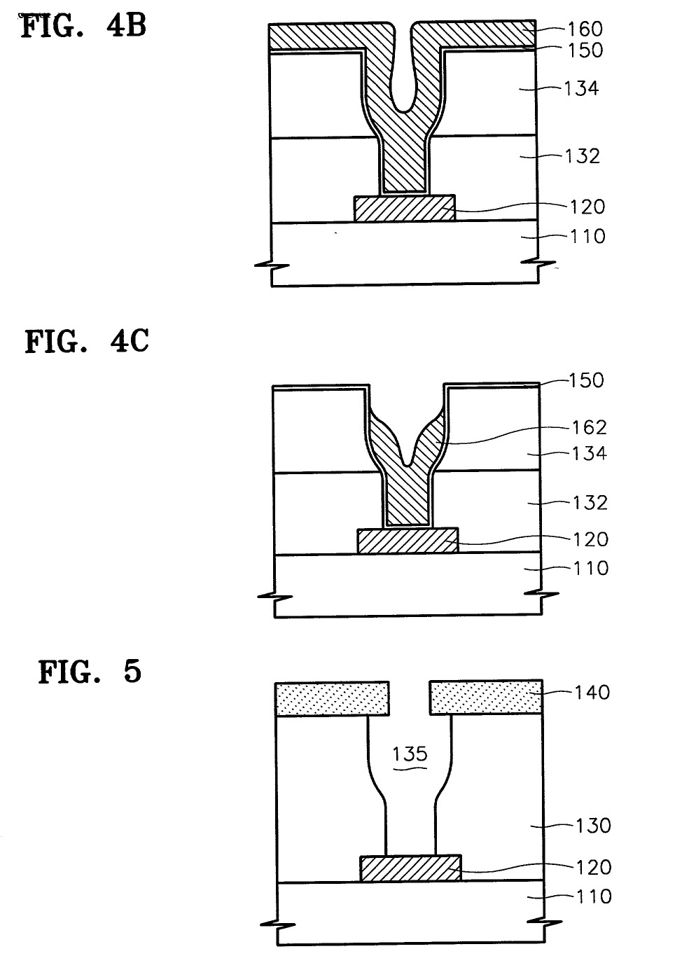

FIGS. 4A through 4C are sectional views showing the processes of forming the metal contact structure according to the embodiments shown in FIGS. 2A and 2B.

Referring to FIG. 4A, the lower conductive layer 120 (this can be an activated region formed on the surface of the substrate) is formed on the substrate 110 (this can be the interlayer dielectric film under which predetermined elements are formed), and the upper and lower interlayer dielectric films 132 and 134 having different etch rates with respect to a predetermined etchant are sequentially deposited on the lower conductive layer 120. For example, the upper interlayer dielectric film 132 is formed of PE-TEOS or PSG and the upper interlayer dielectric film 134 is formed of SOG or USG.

The photoresist pattern 140 that defines the contact hole 135 that exposes the lower conductive layer 120 is formed on the upper interlayer dielectric film 134. The contact hole 135 is formed by sequentially etching the upper and lower interlayer dielectric films 134 and 132 using the photoresist pattern 140 as an etching mask. At this time, when wet etching is performed using an oxide film etchant including an HF solution, since the upper interlayer dielectric film 134 formed of SOG or USG is etched faster than the lower interlayer dielectric film 132 formed of PE-TEOS or PSG, as shown in FIG. 4A, it is possible to obtain the contact hole 135 with an upper portion wider than a lower portion.

Referring to FIG. 4B, the photoresist pattern 140 is removed and the barrier metal layer 150 is formed by depositing the Ti film and the TiN film on the entire surface of the contact hole 135 and the interlayer dielectric film 134 by conventional techniques such as a physical vapor deposition (PVD) method or a chemical vapor deposition (CVD) method. For an ohmic contact between the lower conductive layer 120 and the upper wiring, the barrier metal layer 150 prevents metal interdiffusion. The barrier metal layer 150 may be formed of other metals that satisfy such characteristics or a metal nitride film such as a Ta film and a TaN film.

A tungsten layer 160 or other suitable conductive layer is formed by depositing a metal, for example, W, on the surface of the barrier metal layer 150 by PVD or CVD. At this time, the tungsten layer is deposited to a specific thickness without forming a void, namely, the contact hole is not completely filled. In the first embodiment, since the upper portion of the contact hole is wider than the lower portion of the contact hole, void is not generated even though the tungsten layer is deposited to be thicker than in the conventional technology.

Referring to FIG. 4C, the lower metal layer 162 is formed by planarizing or etching back the tungsten layer 160 of FIG. 4B to leave a portion of the tungsten layer 160 inside the contact hole but remove substantially all of the tungsten layer 160 on the upper portion of the interlayer dielectric film 134. This can be achieved by etching back the tungsten layer 160 using the barrier metal layer 150 as the etching stop layer. To be specific, the tungsten layer 160 is etched by plasma etching using an etching gas including fluorine such as SF₆ or NF₃. Since plasma activity is weak in SF₆ or NF₃ gas, it is possible to add Cl₂ in order to compensate for the weak plasma activity. In order to stop the etch back of the tungsten layer 160 at the surface of the barrier metal layer 150 formed of a TiN film, it is preferable that transformer coupled plasma (TCP) equipment or decoupled plasma source (DSP) equipment, with which high density plasma etching can be performed, is used and that the bias voltage applied to the substrate is less than 100W.

A metal such as tungsten or aluminum, is deposited on the surface of the substrate 110. Then, since the contact hole to be filled was already partially filled by the lower metal layer 162, the contact hole is substantially completely filled to have an excellent profile without a void or key hole. The metal contact structure having the structure shown in FIG. 2A is obtained by patterning the metal layer that is formed on the surface of the substrate, while filling the contact hole, to have a predetermined wiring pattern. When the upper metal layer 164 is formed of tungsten, like the lower metal layer 162, the tungsten layer is appropriately used as a local interconnection since aluminum has higher resistance than aluminum. To provide for longer wiring, the upper metal layer 164 is preferably formed of aluminum.

In order to obtain the metal contact structure as shown in FIG. 2B, after filling the contact hole by depositing a metal layer formed of a metal such as tungsten on the surface of the semiconductor substrate as shown in FIG. 4C and planarizing the metal layer to form the planarized upper metal layer 166 by CMP or etch back, a metal such as aluminum is deposited on the resulting structure, and is patterned to have a predetermined wiring pattern. Although not shown, when the planarized upper metal layer 166 is formed of tunsten and the upper conductive layer 170 is formed of aluminum, it is preferable that the upper conductive layer 170 is formed after the barrier metal layer is formed on the planarized upper metal layer 166 and interlayer dielectric film 134.

FIG. 5 is a sectional view showing the processes of forming the metal contact structure of a second embodiment as shown in FIGS. 3A and 3B. The metal contact structure shown in FIGS. 3A and 3B is different from the metal contact structure shown in FIGS. 2A and 2B only in that the interlayer dielectric film 130 is formed of a single layer as mentioned previously. Therefore, when the interlayer dielectric film 130 is formed of a single layer, only the processes of forming the contact hole having the same shape as shown in the above-mentioned embodiment are described and description of the remaining processes will be omitted.

As shown in FIG. 5, the lower conductive layer 120 and the interlayer dielectric film 130 are formed on the substrate 110 and then, the photoresist pattern 140 to define the contact hole 135 is formed. The upper portion of the contact hole 135 is previously formed by an isotropic etch using the photoresist pattern 140 as the etching mask. Then, the interlayer dielectric film 130 under the photoresist pattern 140 is etched not only in a vertical direction but also in a horizontal direction. Accordingly, the entrance of the upper portion of the contact hole becomes wider than the aperture of the photoresist pattern 140. When the exposed interlayer dielectric film 130 is anisotropically etched using the photoresist pattern 140 as the etching mask, the contact hole 135 having the structure shown in FIG. 5 is obtained. Isotropic etching can be realized by wet etching or plasma etching, which is performed by applying a bias power. Isotropic etching of the interlayer dielectric film 130 is preferably performed using SC1 (NH₄OH+H₂O₂+DI water). Anisotropic etching can be realized by plasma etching, which is performed by applying a bias power. Anisotropic etching of the interlayer dielectric film 130 is preferably performed using a gas mixture of, for example, 28C₄F₆+10C₂F₆+30CH₂F, in a chamber at 40 Torr.

As mentioned above, according to the present invention, a void or key hole is not generated. This is because the upper portion of the contact hole is wider than the lower portion of the contact hole and the metal that fills the contact hole is deposited by the processes of firstly depositing the metal, etching back the metal, and secondly depositing the metal. In particular, when the firstly deposited metal is etched back, problems due to uneven etch back in the conventional technology do not occur as a result of etching back the firstly deposited metal using the barrier metal layer as the etching stop layer.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method for forming a metal contact structure of a semiconductor device, comprising:
forming an interlayer dielectric film on a substrate on which a lower conductive layer is formed;
forming a contact hole through the interlayer dielectric film to expose a region of the lower conductive layer by etching the interlayer dielectric film, the contact hole having a predetermined shape including an upper portion and a lower portion,
wherein a diameter of the upper portion of the contact hole is larger than a diameter of the lower portion of the contact hole;
forming a barrier metal layer on the surface of the interlayer dielectric film including surfaces within the contact hole;
forming a lower metal layer in the lower portion of the contact hole; and
forming an upper metal layer on the lower metal layer.

2. The method of claim 1, wherein forming an interlayer dielectric film comprises sequentially depositing at least two different interlayer dielectric films having different etching rates with respect to a predetermined etchant,
wherein forming a contact hole having the predetermined shape comprises etching the interlayer dielectric film using the predetermined etchant such that the upper interlayer dielectric film is etched more than the lower interlayer dielectric film.

3. The method of claim 2, wherein the upper interlayer dielectric film is formed of spin-on glass (SOG) or undoped silicate glass (USG) and the lower interlayer dielectric film is formed of plasma enhanced tetraethylorthosilicate (PE-TEOS) or phosphorous silicate glass (PSG), and wherein the etching of the interlayer dielectric film for forming the contact hole is performed by wet etching using an etchant including an HF solution.

4. The method of claim 1, wherein forming the contact hole comprises:
forming an etching mask defining the contact hole on the interlayer dielectric film; and
isotropically etching the interlayer dielectric film using the etching mask; and
anisotropically etching the interlayer dielectric film using the etching mask.

5. The method of claim 1, wherein forming a lower metal layer comprises:
depositing a layer of metal for forming the lower metal layer in the contact hole; and
etching back the layer of metal to remove a portion of the layer of metal inside the contact hole until the barrier metal layer is exposed to form the lower metal layer.

6. The method of claim 5, wherein the upper metal layer overlies the substrate including the etched-back lower metal layer and fills the contact hole, and the method further comprises forming an upper wiring by patterning the upper metal layer.

7. The method of claim 5, after forming the upper metal layer on the etched-back lower metal layer, the method further comprises:
forming a contact plug formed of the lower and upper metal layers by removing the upper metal layer deposited on the interlayer dielectric film, the upper portion of the contact hole remaining filled with the upper metal layer; and
forming an upper conductive layer of a predetermined pattern on the contact plug.

8. The method of claim 7, wherein the lower and upper metal layers are formed of tungsten and the upper conductive layer is formed of aluminum.

9. The method of claim 1, wherein the lower and upper metal layers are comprised of tungsten or aluminum.

10. The method of claim 5, after forming an upper metal layer on the etched-back lower metal layer,
repeatedly etching back the upper metal layer and depositing another metal layer over the resulting structure until the contact hole is substantially completely filled without void.

11. The method of claim 1, wherein the barrier metal layer is formed by stacking a Ti film and a TiN film.

12. A metal contact structure of a semiconductor device comprising:
a lower conductive layer;
an interlayer dielectric film having a contact hole formed therein that exposes a region of the lower conductive layer, the interlayer dielectric film having an upper portion and a lower portion,
wherein a diameter of the upper portion of the contact hole is larger than a diameter of the lower portion of the contact hole; and
an upper wiring comprising at least two metal layers including:
a lower metal layer disposed on the lower conductive layer and filling a lower portion of the contact hole and the lower metal layer formed of a first metal, and
an upper metal layer filling the remaining portion of the contact hole and the upper metal layer formed of a second metal disposed on the lower metal layer.

13. The metal contact structure of claim 12, wherein the interlayer dielectric film includes two different layers having different etching rates with respect to a predetermined etchant.

14. The metal contact structure of claim 13, wherein the upper interlayer dielectric film is formed of SOG or USG and the lower interlayer dielectric film is formed of PE-TEOS or PSG.

15. The metal contact structure of claim 12, wherein the upper wiring comprises:
a contact plug formed of the lower metal layer and the upper metal layer and filling the contact hole; and
an upper conductive layer formed on the contact plug having a predetermined pattern.

16. The metal contact structure of claim 15, wherein the lower and upper metal layers are formed of aluminum and the upper conductive layer is formed of aluminum.

17. The metal contact structure of claim 12, wherein the lower and upper metal layer are formed of tungsten or aluminum.
